(19) United States
(12) Patent Application Publication
(10) Pub. No.: US 2017/0137658 A1
(43) Pub. Date: May 18, 2017

(54) FLUOROPOLYMER COMPOSITIONS

(71) Applicants: SOLVAY SPECIALTY POLYMERS ITALY S.P.A., Bollate (IT); RHODIA OPERATIONS, Paris (FR)

(72) Inventors: Alessio MARRANI, Lecco (IT); Fiorenza D'APRILE, Nova Milanese (IT); Ivan FALCO, Sedriano (IT); Arnaud BOURDETTE, Chelles (FR)

(21) Appl. No.: 15/309,668

(22) PCT Filed: May 6, 2015
(86) PCT No.: PCT/EP2015/059924

§ 371 Date: Nov. 8, 2016

(30) Foreign Application Priority Data
May 9, 2014 (EP) 14305678.6

(51) Int. Cl. C09D 127/16; C23C 16/56; H01L 41/317; H01L 41/45; C08J 3/09; H01L 41/193

(52) U.S. Cl. CPC C09D 127/16; C08J 3/095; H01L 41/193; H01L 41/317; H01L 41/45; C23C 16/56; C08J 2327/16

(57) ABSTRACT

The present invention pertains to a fluoropolymer composition, to a process for the manufacture of said fluoropolymer composition and to uses of said fluoropolymer composition in various applications, in particular to uses of fluoropolymer films obtainable therefrom in electrical or electronic devices.

This application claims priority to European application No. EP 14305678.6 filed on May 9, 2014, the whole content of this application being incorporated herein by reference for all purposes.

### TECHNICAL FIELD

The present invention pertains to a fluoropolymer composition, to a process for the manufacture of said fluoropolymer composition and to uses of said fluoropolymer composition in various applications.

### BACKGROUND ART

Vinylidene fluoride (VDF) copolymers comprising recurring units derived from trifluoroethylene (TrFE) have been used extensively in the manufacture of electronic devices due to their ease of processing, chemical inertness and attractive ferroelectric, piezoelectric, pyroelectric and dielectric properties.

As is well known, the term piezoelectric means the ability of a material to exchange electrical for mechanical energy and vice versa and the electromechanical response is believed to be essentially associated with dimensional changes during deformation or pressure oscillation. The piezoelectric effect is reversible in that materials exhibiting the direct piezoelectric effect (the production of electricity when stress is applied) also exhibit the converse piezoelectric effect (the production of stress and/or strain when an electric field is applied).

Ferroelectricity is the property of a material whereby this latter exhibits a spontaneous electric polarization, the direction of which can be switched between equivalent states by the application of an external electric field.

Pyroelectricity is the ability of certain materials to generate an electrical potential upon heating or cooling. Actually, as a result of this change in temperature, positive and negative charges move to opposite ends through migration (i.e. the material becomes polarized) and hence an electrical potential is established.

It is generally understood that piezo-, pyro-, ferro-electricity in copolymers of VDF with TrFE is related to a particular crystalline habit, so called beta-phase, wherein hydrogen and fluorine atoms are arranged to give maximum dipole moment per unit cell.

Copolymers comprising recurring units derived from vinylidene fluoride (VDF) and trifluoroethylene (TrFE) are typically provided as semi-crystalline copolymers which can be shaped or formed into semi-crystalline, essentially unoriented and unstretched, thermoplastic films or sheets or tubular-constructed products via well-known processing methods such as extrusion, injection moulding, compression moulding and solvent casting.

Nevertheless, more recently, developments of thin film electronic devices and/or assemblies of layers of ferroelectric polymers in three-dimensional arrays for increasing e.g. memory density have called for different processing techniques, requiring notably ability of the polymer to be patterned according to lithographic techniques and/or for layers there from to be stacked with annealing treatment on newly formed layer not affecting previously deposited layers.

In these techniques, it remains nevertheless key to provide for stable and homogeneous solutions of fluorinated polymers as starting materials.

The vast majority of fluorinated polymers can be readily dissolved in suitable solvents to form stable solutions. These solvents include N-methylpyrrolidone (NMP), N,N-dimethylacetamide (DMAC), N,N-dimethylformamide (DMF), dimethyl sulphoxide (DMSO) and phthalates.

With regards to NMP, DMF and DMAC, which have been since years the solvents of choice in the industry in solution-based processes for the manufacture of thin film electronic devices, these solvents are now facing environmental and safety concerns, having regards to the safety risks associated to their handling and to possible leakage/emissions in the environment, so questing for substitution.

For instance, NMP has been notably classified according to the European regulation (EC) No1272/2008 in the hazard class Repr.1B code H360D (may damage the unborn child), Eye Irrit.2 code H319, STOT SE 3 code H335, Skin Irrit.2 H315 and according to the European directive 67/548/EEC it is classified as Reprotoxic Cat2 code R61, Xi codes R36/37/38. Further more it is submitted to the Toxic Release Inventory (SARA Title III Section 313).

Similarly, DMAC is covered by index number 616-011-00-4 of Regulation (EC) No 1272/2008 in Annex VI, part 3, Table 3.1 (the list of harmonised classification and labelling of hazardous substances) as toxic for reproduction category 1B (H360D: “May damage the unborn child”). The corresponding classification in Annex VI, part 3, Table 3.2 (the list of harmonised and classification and labelling of hazardous substances from Annex Ito Directive 67/548/EEC) of Regulation (EC) No 1272/2008 is toxic to reproduction category 2 (R61: “May cause harm to the unborn child”).

Also, DMF has been classified as toxic to reproduction category 1B (H360D: “May damage the unborn child”) according to Regulation (EC) No 1272/2008 and is included in Annex VI, part 3 (index number 616-001-00-X), Table 3.1 (list of harmonised classification and labelling of hazardous substances). The corresponding classification in Annex VI, part 3, Table 3.2 (the list of harmonised classification and labelling of hazardous substances from Annex I to Directive 67/548/EEC) of Regulation (EC) No 1272/2008 is toxic to reproduction category 2 (R61: “May cause harm to the unborn child.”).

The present invention thus provides a solution for obviating to environmental and safety concerns which arise in using NMP, DMF, DMAC, phthalates or other similar solvents and provides an alternative process for manufacturing fluoropolymer compositions and films thereof.

### SUMMARY OF INVENTION

It has been now found that by using the composition of the present invention it is advantageously possible to solubilize certain fluoropolymers at relatively low temperatures while avoiding use of toxic organic solvents.

In a first instance, the present invention pertains to a composition [composition (C)] comprising:

(A) at least one fluoropolymer [polymer (F)] comprising:
from 30% to 82% by moles, with respect to the total amount by moles of recurring units of the polymer (F), of recurring units derived from vinylidene fluoride (VDF) and
from 18% to 70% by moles, with respect to the total amount by moles of recurring units of the polymer (F), of recurring units derived from trifluoroethylene (TrFE) and, optionally, from at least one fluorinated monomer [monomer (F)] different from VDF and TrFE, and

(B) a liquid medium [medium (L)] comprising one or more organic solvents selected from the group consisting of diesters of formula (I_{de}), esteramides of formula (Iₑₐ) and diamides of formula (I_{da}):

R¹O(O)C—Z_{de}—C(O)OR² (I_{de})

R³O(O)C—Zₑₐ—C(O)NR⁴R⁵ (Iₑₐ)

R⁵R⁴N(O)C—Z_{da}—C(O)NR⁴R⁵ (I_{da})

wherein:
R¹ and R², equal to or different from each other, are independently selected from the group consisting of C₁-C₃ hydrocarbon groups,
R³ is selected from the group consisting of C₁-C₂₀ hydrocarbon groups, and
R⁴ and R⁵, equal to or different from each other, are independently selected from the group consisting of hydrogen and C₁-C₃₆ hydrocarbon groups, optionally substituted, being understood that R⁴ and R⁵ might be part of a cyclic moiety including the nitrogen atom to which they are bound, said cyclic moiety being optionally substituted and/or optionally comprising one or more heteroatoms, and mixtures thereof, and
Z_{de}, Zₑₐ and Z_{da}, equal to or different from each other, are independently linear or branched C₂-C₁₀ divalent alkylene groups.

For the purpose of the present invention, the term “liquid medium [medium (L)]” is intended to denote a medium comprising one or more compounds in liquid state at 20° C. under atmospheric pressure.

For the purpose of the present invention, the term “organic solvent” is used in its usual meaning, that is to say that it refers to an organic compound capable of dissolving another compound (solute) to form a uniformly dispersed mixture at molecular level. In the case the solute is a polymer such as the polymer (F), it is common practice to refer to a solution of the polymer in a solvent when the resulting mixture is clear and no phase separation is visible in the system. Phase separation is taken to be the point, often referred to as “cloud point”, at which the solution becomes turbid or cloudy due to formation of polymer aggregates or at which the solution turns into a gel.

The term “gel” is used herein in its usual meaning, that is to say that it refers to a substance which does not flow.

It has been found that the composition (C) of the invention is advantageously a homogenous solution wherein at least one polymer (F) is successfully dissolved in the medium (L) thereby providing a clear solution with no phase separation.

In a second instance, the present invention pertains to a process for the manufacture of the composition (C) of the invention, said process comprising:
(i) providing a mixture comprising at least one polymer (F) and a medium (L), and
(ii) heating under stirring the mixture provided in step (i) thereby providing the composition (C).

Under step (ii) of the process for the manufacture of the composition (C), the mixture provided in step (i) is typically heated under stirring at a temperature of at least 20° C., preferably of at least 25° C.

Under step (ii) of the process for the manufacture of the composition (C), the mixture provided in step (i) is typically heated under stirring at a temperature of at most 80° C., preferably of at most 70° C.

It has been found that the process of the invention may be advantageously carried out at a temperature not higher than 70° C., preferably not higher than 80° C.

In a third instance, the present invention pertains to a process for the manufacture of a fluoropolymer film [film (F)], said process comprising:
(i′) providing a substrate,
(ii′) providing a composition [composition (C)] as defined above,
(iii′) applying the composition (C) provided in step (ii′) onto at least one surface of the substrate provided in step (i′) thereby providing a wet film, and
(iv′) drying the wet film provided in step (iii′) thereby providing the fluoropolymer film [film (F)].

It has been found that the film (F) obtainable by the process of the invention is advantageously a homogeneous fluoropolymer film having good mechanical properties to be suitably used in various applications.

For the purpose of the present invention, the term “film” is intended to denote a flat piece of material having a thickness smaller than either of its length or its width.

For the purpose of the present invention, the term “substrate” is intended to denote either a porous or a non-porous substrate.

By the term “porous substrate” it is hereby intended to denote a substrate layer containing pores of finite dimensions. By the term “non-porous substrate” it is hereby intended to denote a dense substrate layer free from pores of finite dimensions.

Under step (iii′) of the process for the manufacture of the film (F), the composition (C) is applied onto at least one surface of the substrate provided in step (i′) typically by using a processing technique selected from the group consisting of casting, spray coating, roll coating, doctor blading, slot die coating, gravure coating, ink jet printing, spin coating, screen printing, brush, squeegee, foam applicator, curtain coating and vacuum coating.

Under step (iv′) of the process for the manufacture of the film (F), the wet film provided in step (iii′) is dried typically at a temperature comprised between 60° C. and 200° C., preferably at a temperature comprised between 70° C. and 130° C.

Drying can be performed either under atmospheric pressure or under vacuum. Alternatively, drying can be performed under modified atmosphere, e.g. under an inert gas, typically exempt notably from moisture (water vapour content of less than 0.001% v/v).

The drying temperature will be selected so as to effect removal by evaporation of one or more organic solvents from the film (F) of the invention.

The present invention thus also pertains to the fluoropolymer film [film (F)] obtainable by the process of the invention.

The film (F) typically consists of a composition comprising at least one polymer (F).

The film (F) is typically free from any organic solvent.

The composition (C) may further comprise one or more additives.

The choice of the additives is not particularly limited provided that they do not interfere with solubility of the polymer(s) (F) in the medium (L).

Non-limitative examples of suitable additives include, notably, pigments, UV absorbers, crosslinking agents, crosslinking initiators, organic and inorganic fillers such as ceramics, glass, silica, conductive metal particles, semiconductive oxides, carbon nanotubes, graphenes, core-shell particles, encapsulated particles, conductive salts, silicon-based particles.

Should the composition (C) further comprise one or more additives, the film (F) thereby provided typically consists of a composition comprising at least one polymer (F) and at least one additive.

Should the composition (C) further comprise one or more additives selected from the group consisting of crosslinking agents and crosslinking initiators, the film (F) thereby provided is advantageously a crosslinkable fluoropolymer film [film (FC)] which typically consists of a composition comprising at least one polymer (F) and at least one additive selected from the group consisting of crosslinking agents and crosslinking initiators.

The crosslinking agent is typically a poly(meth)acrylic compound [compound (PMA)] comprising end groups of formula:

—O—C(O)—C(R⁶)═CR⁷R⁸

wherein each of R⁶, R⁷ and R⁸, equal to or different from each other, is independently a hydrogen atom or a C₁-C₃ hydrocarbon group.

The compound (PMA) is more preferably selected from the group consisting of ethylene glycol di(meth)acrylate, diethylene glycol di(meth)acrylate, triethylene glycol di(meth)acrylate, tetraethylene glycol di(meth)acrylate, polyethylene glycol di(meth)acrylate, 1,6-hexanediol di(meth)acrylate, 1,3-butylene glycol di(meth)acrylate, tripropylene glycol di(meth)acrylate, ethoxylated bisphenol A di(meth)acrylate, cyclohexane dimethanol di(meth)acrylate, tris[2-(acryloyloxy)ethyl]isocyanurate, trimethylol propane triacrylate, ethylene oxide added trimethylol propane triacrylate, pentaerythritol triacrylate, tris(acrylooxyethyl)isocyanurate, dipentaerythritol hexaacrylate and caprolactone denatured dipentaerythritol hexaacrylate.

The crosslinking initiator may be a photoinitiator [initiator (PI)] or a thermal initiator [initiator (TI)].

The photoinitiator [initiator (PI)] is typically selected from the group consisting of alpha-hydroxyketones, phenylglyoxylates, benzyldimethyl ketals, alpha-aminoketones and bis acyl phosphines.

Among alpha-hydroxyketones, mention can be made of 1-hydroxy-cyclohexyl-phenyl-ketone, 2-hydroxy-2-methyl-1-phenyl-1-propanone and 2-hydroxy-1-[4-(2-hydroxyethoxy)phenyl]-2-methyl-1-propanone.

Among phenylglyoxylates, mention can be made of methylbenzoylformate, oxy-phenyl-acetic acid 2-[2-oxo-2-phenyl-acetoxy-ethoxy]-ethyl ester and oxy-phenyl-acetic 2-[2-hydroxy-ethoxy]-ethyl ester.

Among benzyldimethyl ketals, mention can be made of alpha, alpha-dimethoxy-alpha-phenylacetophenone.

Among alpha-aminoketones, mention can be made of 2-benzyl-2-(dimethylamino)-1-[4-(4-morpholinyl) phenyl]-1-butanone and 2-methyl-1-[4-(methylthio)phenyl]-2-(4-morpholinyl)-1-propanone.

Among bis acyl phosphines, mention can be made of diphenyl-(2,4,6-trimethylbenzoyl)-phosphine oxide.

Among initiators (PI), those which are liquid at room temperature are preferred.

A class of initiators (PI) which gave particularly good results has been that of alpha-hydroxyketones, in particular 2-hydroxy-2-methyl-1-phenyl-1-propanone.

The amount of initiator (PI) in the composition (C) is not particularly limited. It will be generally used in an amount comprised between 0.01% and 10% by weight, with respect to the total weight of the composition (C). According to an embodiment of the invention, the composition (C) comprises at least one initiator (PI) in an amount comprised between 3% and 7% by weight, with respect to the total weight of the composition (C).

The thermal initiator [initiator (TI)] is typically selected from the group consisting of organic peroxides.

The crosslinkable fluoropolymer film [film (FC)] is crosslinked typically either by UV treatment under UV radiation or by thermal treatment.

For the purpose of the present invention, the term “UV radiation” is intended to denote electromagnetic radiation with a wavelength shorter than that of visible light but longer than soft X-rays. It can be subdivided into near UV (380-200 nm wavelength; abbreviation: NUV), far or vacuum UV (200-10 nm; abbreviation: FUV or VUV), and extreme UV (1-31 nm; abbreviation: EUV or XUV). NUV having a wavelength of from 200 nm to 380 nm is preferred in the process of the invention. Either monochromatic or polychromatic radiation can be used.

UV radiation can be provided in the crosslinking process of the invention by any suitable UV radiation source.

Thermal treatment is typically carried out at a temperature comprised between 60° C. and 150° C., preferably between 100° C. and 135° C.

The crosslinkable fluoropolymer film [film (FC)] may be a patterned crosslinkable fluoropolymer film [film (FCp)].

For the purpose of the present invention, the term “patterned crosslinkable fluoropolymer film [film (FCp)]” is intended to denote a fluoropolymer film having whichever pattern geometry.

In a fourth instance, the present invention pertains to use of at least one fluoropolymer film [film (F)] in an electrical or electronic device.

The present invention thus further pertains to a process for the manufacture of an electrical or electronic device, said process comprising:
(i″) manufacturing a fluoropolymer film [film (F)] according to the process of the invention, and
(ii″) using the film (F) provided in step (i″) for manufacturing said electrical or electronic device.

Non-limitative examples of suitable electronic devices include transducers, sensors, actuators, ferroelectric memories and capacitors powdered by electrical devices.

The composition (C) advantageously comprises:

(A) from 0.1% to 40% by weight of at least one polymer (F) and

(B) from 60% to 99.9% by weight of a medium (L).

The composition (C) typically comprises:

(A) from 0.2% to 30% by weight of at least one polymer (F) and

(B) from 70% to 99.8% by weight of a medium (L).

For the purpose of the present invention, the term “fluorinated monomer [monomer (F)]” is intended to denote an ethylenically unsaturated monomer comprising at least one fluorine atom.

Non-limitative examples of suitable monomers (F) notably include the followings:
(a) C₂-C₈ perfluoroolefins such as tetrafluoroethylene (TFE) and hexafluoropropylene (HFP);
(b) perfluoroalkylethylenes of formula CH₂═CH—R_{f0}, wherein R_{f0} is a C₂-C₆ perfluoroalkyl group;
(c) chloro- and/or bromo- and/or iodo-C₂-C₆ fluoroolefins such as chlorofluoroethylene (CFE) and chlorotrifluoroethylene (CTFE);
(d) perfluoroalkylvinylethers of formula CF₂═CFOR_{f1}, wherein R_{f1} is a C₁-C₆ perfluoroalkyl group, such as perfluoromethylvinylether (PMVE) and perfluoropropylvinylether (PPVE);
(e) (per)fluorooxyalkylvinylethers of formula CF₂═CFOX₀, wherein X₀ is a C₁-C₁₂ oxyalkyl group or a C₁-C₁₂ (per)fluorooxyalkyl group having one or more ether groups, e.g. perfluoro-2-propoxy-propyl group;
(f) (per)fluoroalkylvinylethers of formula CF₂═CFOCF₂OR_{f2}, wherein R_{f2} is a C₁-C₆ (per)fluoroalkyl group, e.g. —CF₃, —C₂F₅, —C₃F₇, or a C₁-C₆ (per)fluorooxyalkyl group having one or more ether groups, e.g. —C₂F₅—O—CF₃;
(g) functional (per)fluorooxyalkylvinylethers of formula CF₂═CFOY₀, wherein Y₀ is selected from a C₁-C₁₂ alkyl group or (per)fluoroalkyl group, a C₁-C₁₂ oxyalkyl group and a C₁-C₁₂ (per)fluorooxyalkyl group having one or more ether groups, Y₀ comprising a carboxylic or sulfonic acid group, in its acid, acid halide or salt form;
(h) fluorodioxoles, preferably perfluorodioxoles such as 2,2,4-trifluoro-5-trifluoromethoxy-1,3-dioxole.

Most preferred monomers (F) are chlorofluoroethylene (CFE), chlorotrifluoroethylene (CTFE), perfluoromethylvinylether (PMVE), tetrafluoroethylene (TFE) and hexafluoropropylene (HFP).

The polymer (F) may further comprise recurring units derived from at least one hydrogenated monomer [monomer (H)].

For the purpose of the present invention, the term “hydrogenated monomer [monomer (H)]” is hereby intended to denote an ethylenically unsaturated monomer comprising at least one hydrogen atom and free from fluorine atoms.

The monomer (H) is typically selected from the group consisting of (meth)acrylic monomers of formula (II) and vinyl ether monomers of formula (III):

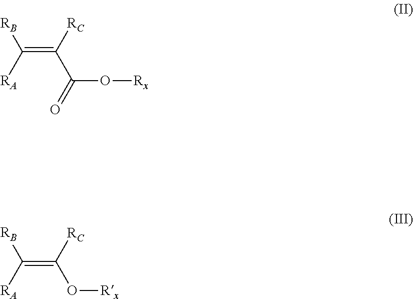

wherein each of RA, RB and Rc, equal to or different from each other, is independently a hydrogen atom or a C₁-C₃ hydrocarbon group, Rx is a hydrogen atom or a C₁-C₅ hydrocarbon group comprising at least one hydroxyl group, and R′ₓ is a C₁-C₅ hydrocarbon group comprising at least one hydroxyl group.

The polymer (F) may be amorphous or semi-crystalline.

The term “amorphous” is hereby intended to denote a polymer (F) having a heat of fusion of less than 5 J/g, preferably of less than 3 J/g, more preferably of less than 2 J/g, as measured according to ASTM D-3418-08.

The term “semi-crystalline” is hereby intended to denote a polymer (F) having a heat of fusion of from 10 J/g to 90 J/g, preferably of from 30 J/g to 60 J/g, more preferably of from 35 J/g to 55 J/g, as measured according to ASTM D3418-08.

The polymer (F) has typically a heat of fusion of from 10 J/g to 80 J/g, preferably of from 10 J/g to 60 J/g, more preferably of from 10 J/g to 55 J/g, as measured according to ASTM D3418.

The polymer (F) has typically a melt flow index of at most 500 g/10 min, preferably of at most 200 g/10 min, more preferably of at most 50 g/10 min, as measured according to ASTM D1238 (230° C., 5 Kg).

The polymer (F) has typically a melt flow index of at least 0.1 g/10 min, preferably of at least 1 g/10 min, more preferably of at least 1.5 g/10 min, as measured according to ASTM D1238 (230° C., 5 Kg).

According to a first preferred embodiment of the invention, the polymer (F) comprises:
from 45% to 81% by moles, with respect to the total amount by moles of recurring units of the polymer (F), of recurring units derived from vinylidene fluoride (VDF),
from 19% to 55% by moles, with respect to the total amount by moles of recurring units of the polymer (F), of recurring units derived from trifluoroethylene (TrFE) and
optionally, from 0.01% to 15% by moles, with respect to the total amount by moles of recurring units of the polymer (F), of recurring units derived from at least one monomer (H).

According to a second preferred embodiment of the invention, the polymer (F) comprises:
from 30% to 80% by moles, with respect to the total amount by moles of recurring units of the polymer (F), of recurring units derived from vinylidene fluoride (VDF),
from 19% to 55% by moles, with respect to the total amount by moles of recurring units of the polymer (F), of recurring units derived from trifluoroethylene (TrFE),
from 1% to 15% by moles, with respect to the total amount by moles of recurring units of the polymer (F), of recurring units derived from at least one monomer (F) different from VDF and TrFE and
optionally, from 0.01% to 8% by moles, with respect to the total amount by moles of recurring units of the polymer (F), of recurring units derived from at least one monomer (H).

The polymer (F) can be manufactured either by aqueous suspension polymerization or by aqueous emulsion polymerization.

The polymer (F) is preferably manufactured by aqueous emulsion polymerization of vinylidene fluoride (VDF), trifluoroethylene (TrFE), optionally, at least one monomer (F) different from VDF and TrFE and, optionally, at least one monomer (H) in the presence of at least one radical initiator in a polymerization medium comprising:
water,
at least one surfactant and
optionally, at least one non-functional perfluoropolyether oil.

Polymerization pressure ranges typically between 10 bar and 45 bar, preferably between 15 bar and 40 bar, more preferably between 20 bar and 35 bar.

The skilled in the art will choose the polymerization temperature having regards, inter alia, of the radical initiator used. Polymerization temperature is generally selected in the range comprised between 80° C. and 140° C., preferably between 95° C. and 130° C.

Emulsion polymerization process as detailed above have been described in the art (see e.g. U.S. Pat. No. 4,990,283 (AUSIMONT SPA (IT)) Feb. 5, 1991, U.S. Pat. No. 5,498,680 (AUSIMONT SPA) Mar. 12, 1996 and U.S. Pat. No. 6,103,843 (AUSIMONT SPA) Aug. 15, 2000).

Should the polymer (F) be manufactured by aqueous suspension polymerization, the polymerization medium typically results in an aqueous slurry comprising the polymer (F) from which said polymer (F) is recovered by concentration and/or coagulation of said aqueous slurry and then submitted to drying.

Should the polymer (F) be manufactured by aqueous emulsion polymerization, the polymerization medium typically results in an aqueous latex comprising the polymer (F) and at least one surfactant from which said polymer (F) is recovered by concentration and/or coagulation of said aqueous latex and then submitted to drying.

Drying is typically carried out in suitable heating devices, generally electric ovens or convection ovens. Drying is carried out at a temperature typically up to 300° C., preferably up to 200° C., more preferably up to 100° C. Drying is carried out for a time typically of from 1 to 60 hours, preferably of from 10 to 50 hours.

The polymer (F) is typically recovered by the polymerization medium in the form of particles. The polymer (F) is commonly recovered by the polymerization medium in the form of particles such as flakes, rods, thread-like particles and mixtures thereof.

The polymer (F) particles recovered by the polymerization medium may be further processed by melt-processing techniques thereby providing pellets.

Under step (i) of the process for the manufacture of the composition (C), the polymer (F) may be used either in the form of particles or in the form of pellets.

Under step (i) of the process for the manufacture of the composition (C), the polymer (F) is preferably used in the form of particles such as flakes, rods, thread-like particles and mixtures thereof.

The particle size of the polymer (F) is not particularly limited. The skilled in the art will select the proper particle size of the polymer (F) in order to suitably adjust its time of dissolution in the medium (L).

The polymer (F) is advantageously a linear polymer [polymer (F_{L})] comprising linear sequences of recurring units derived from vinylidene fluoride (VDF), trifluoroethylene (TrFE), optionally, at least one monomer (F) different from VDF and TrFE and, optionally, at least one monomer (H).

The polymer (F) is thus typically distinguishable from graft polymers.

The polymer (F) is advantageously a random polymer [polymer (F_{R})] comprising linear sequences of randomly distributed recurring units derived from vinylidene fluoride (VDF), trifluoroethylene (TrFE), optionally, at least one monomer (F) different from VDF and TrFE and, optionally, at least one monomer (H).

The polymer (F) is thus typically distinguishable from block polymers.

The polymer (F) typically comprises one or more chain branches comprising end groups of formulae —CF₂H and/or —CF₂CH₃, which usually originate from intra-chain transfer (back-biting) during radical polymerization as shown in the scheme here below:

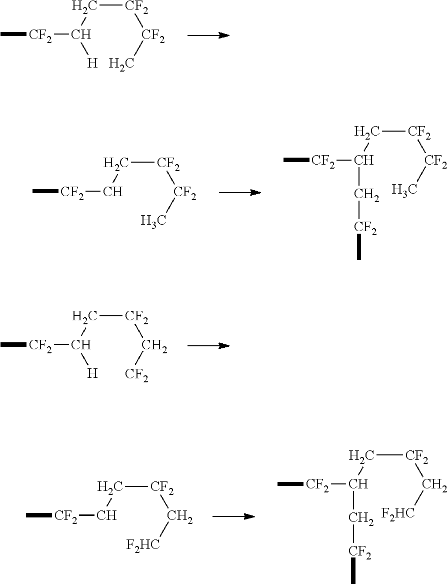

According to a first embodiment of the invention, the polymer (F) comprises one or more chain branches comprising end groups of formula —CF₂H and/or —CF₂CH₃ in an amount of less than 30 mmoles per Kg of vinylidene fluoride (VDF) recurring units, preferably of less than 20 mmoles per Kg of VDF recurring units [polymer (F-A)].

According to a second embodiment of the invention, the polymer (F) comprises one or more chain branches comprising end groups of formula —CF₂H and/or —CF₂CH₃ in an amount of at least 30 mmoles per Kg of vinylidene fluoride (VDF) recurring units, preferably of at least 40 mmoles per Kg of VDF recurring units [polymer (F-B)].

The polymer (F) is preferably a polymer (F-B) according to this second embodiment of the invention.

It has been found that the polymer (F-B) may advantageously dissolve faster in the medium (L).

Also, it has been found that the polymer (F-B) may advantageously provide for a composition (C) advantageously comprising dissolved therein up to 40% by weight of at least one polymer (F-B) in the medium (L).

The medium (L) typically comprises a total amount of one or more organic solvents selected from the group consisting of diesters of formula (I_{de}), esteramides of formula (Iₑₐ) and diamides of formula (I_{da}) as defined above of at least 50% by weight, preferably at least 60% by weight, more preferably at least 70% by weight, with respect to the total weight of the medium (L).

In formula (I_{de}), R¹ and R², equal to or different from each other, are preferably independently selected from the group consisting of C₁-C₃alkyl groups such as methyl, ethyl and n-propyl groups, more preferably being methyl groups.

In formula (Iₑₐ), R³ is preferably selected from the group consisting of C₁-C₂₀ alkyl groups.

In formulae (Iₑₐ) and (I_{da}), R⁴ and R⁵, equal to or different from each other, are preferably independently selected from the group consisting of C₁-C₂₀ alkyl, C₁-C₂₀ aryl, C₁-C₂₀ alkyaryl and C₁-C₂₀ arylalkyl groups, all said groups optionally comprising one or more substituents, optionally comprising one or more heteroatoms, and cyclic moieties comprising both R⁴ and R⁵ and the nitrogen atom to which they are bound, said cyclic moieties optionally comprising one or more heteroatoms such as oxygen atoms or additional nitrogen atoms.

The expression “C₁-C₂₀ alkyl” is used according to its usual meaning and it encompasses notably linear, cyclic, branched saturated hydrocarbon groups having from 1 to 20 carbon atoms, preferably from 1 or 2 to 10 carbon atoms, more preferably from 1 to 3 carbon atoms.

The expression “C₁-C₂₀ aryl” is used according to its usual meaning and it encompasses notably aromatic mono- or poly-cyclic groups, preferably mono- or bi-cyclic groups, comprising from 6 to 12 carbon atoms, preferably phenyl or naphthyl groups.

The expression “C₁-C₂₀ arylalkyl” is used according to its usual meaning and it encompasses linear, branched or cyclic saturated hydrocarbon groups comprising, as substituent, one or more aromatic mono- or poly-cyclic groups such as benzyl groups.

The expression “C₁-C₂₀ alkylaryl” is used according to its usual meaning and it encompasses aromatic mono- or poly-cyclic groups comprising, as substituent, one or more alkyl groups such as linear, cyclic, branched saturated hydrocarbon chains having from 1 to 14 carbon atoms and preferably from 1 or 2 to 10 carbon atoms.

In formula (Iₑₐ), R³ is more preferably selected from the group consisting of methyl, ethyl, hydroxyethyl, n-propyl, isopropyl, n-butyl, isobutyl, terbutyl, n-pentyl, isopentyl, n-hexyl and cyclohexyl groups, most preferably from the group consisting of methyl, ethyl and hydroxyethyl groups.

According to a first embodiment of the invention, Z_{de} in formula (I_{de}), Zₑₐ in formula (Iₑₐ) and Z_{da} in formula (I_{da}) are branched C₂-C₁₀ divalent alkylene groups, preferably branched C₃-C₆ divalent alkylene groups.

According to this first embodiment of the invention, Z_{de} in formula (I_{de}), Zₑₐ in formula (Iₑₐ) and Z_{da} in formula (I_{da}) are preferably selected from the group consisting of:
Z_{MG} groups of formula —CH(CH₃)—CH₂—CH₂-(MGₐ) or —CH₂—CH₂—CH(CH₃)-(MG_{b}),
Z_{ES} groups of formula —CH(C₂H₅)—CH₂-(ESₐ) or —CH₂—CH(C₂H₅)-(ES_{b}), and
mixtures thereof.

According to a first variant of this first embodiment of the invention, the medium (L) comprises:

(a′) at least one diester of formula (I′_{de}), at least one diester of formula (I″_{de}) and, optionally, at least one diester of formula (I′″_{de}), or

(b′) at least one esteramide of formula (I′ₑₐ), at least one esteramide of formula (I″ₑₐ) and, optionally, at least one esteramide of formula (I′″ₑₐ), or

(c′) at least one esteramide of formula (I′ₑₐ), at least one esteramide of formula (I″ₑₐ), at least one diamide of formula (I′_{da}), at least one diamide of formula (I″_{da}) and, optionally, at least one esteramide of formula (I′″ₑₐ) and/or at least one diamide of formula (I′″_{da}), or

(d′) combinations of (a′) and/or (b′) and/or (c′),

wherein:

is R¹—O(O)C—Z_{MG}—C(O)O—R² (I′_{de})

is R³—O(O)C—Z_{MG}—C(O)NR⁴R⁵ (I′ₑₐ)

is R⁵R⁴N(O)C—Z_{MG}—C(O)NR⁴R⁵ (I′_{da})

is R¹—O(O)C—Z_{ES}—C(O)O—R² (I″_{de})

is R³—O(O)C—Z_{ES}—C(O)NR⁴R⁵ (I″ₑₐ)

is R⁵R⁴N(O)C—Z_{ES}—C(O)NR⁴R⁵ (I″_{da})

is R¹—O(O)C—(CH₂)₄—C(O)O—R² and (I′″_{de})

is R³—O(O)C—(CH₂)₄—C(O)NR⁴R⁵ (I′″ₑₐ)

is R⁵R⁴N(O)C—(CH₂)₄—C(O)NR⁴R⁵ (I′″_{da})

wherein:
Z_{MG} is of formula —CH(CH₃)—CH₂—CH₂-(MGₐ) or —CH₂—CH₂—CH(CH₃)-(MG_{b}),
Z_{ES} is of formula —CH(C₂H₅)—CH₂-(ESₐ) or —CH₂—CH(C₂H₅)-(ES_{b}),
R¹ and R², equal to or different from each other, are independently selected from the group consisting of C₁-C₃ alkyl groups,
R³ is selected from the group consisting of C₁-C₂₀ alkyl, C₁-C₂₀ aryl, C₁-C₂₀ alkyaryl and C₁-C₂₀ arylalkyl groups, and
R⁴ and R⁵, equal to or different from each other, are independently selected from the group consisting of C₁-C₂₀ alkyl, C₁-C₂₀ aryl, C₁-C₂₀ alkyaryl, arylalkyl groups, all said groups optionally comprising one or more substituents, optionally having one or more heteroatoms, and cyclic moieties comprising both R⁴ and R⁵ and the nitrogen atom to which they are bound, said cyclic moieties optionally comprising one or more heteroatoms such as oxygen atoms or additional nitrogen atoms.

In above mentioned formulae (I′_{de}), (I″_{de}), (I′ₑₐ), (I″ₑₐ), (I′_{da}), (I″_{da}), R¹, R² and R³, equal to or different from each other, are preferably methyl groups, and R⁴ and R⁵, equal to or different from each other, are preferably selected from the group consisting of methyl, ethyl and hydroxyethyl groups.

According to this first variant of the first embodiment of the invention, the medium (L) may comprise:

(aa′) a diester mixture consisting essentially of:
from 70% to 95% by weight of at least one diester of formula (I′_{de}),
from 5% to 30% by weight of at least one diester of formula (I″_{de}) and
from 0 to 10% by weight of at least one diester of formula (I′″_{de}), as defined above, or

(bb′) an esteramide mixture consisting essentially of:
from 70% to 95% by weight of at least one esteramide of formula (I′ₑₐ),
from 5% to 30% by weight of at least one esteramide of formula (I″ₑₐ) and
from 0 to 10% by weight of at least one esteramide of formula (I′″ₑₐ), as defined above, or

(cc′) a diester/esteramide/diamide mixture consisting essentially of:
from 1.4% to 1.9% by weight of at least one diester of formula (I′_{de}),
from 0.1% to 0.6% by weight of at least one diester of formula (I″_{de}),
from 0 to 0.2% by weight of at least one diester of formula (I′″_{de}),
from 70% to 95% by weight of at least one esteramide of formula (I′ₑₐ),
from 5% to 30% by weight of at least one esteramide of formula (I″ₑₐ),
from 0 to 10% by weight of at least one esteramide of formula (I′″ₑₐ),
from 0.01% to 10% by weight of at least one diamide of formula (I′_{da}),
from 0.01% to 5% by weight of at least one diamide of formula (I″_{da}) and
from 0 to 1% by weight of at least one diamide of formula (I′″_{da}), or (dd′) mixtures of (aa′) and/or (bb′) and/or (cc′), as defined above.

Non-limitative examples of suitable media (L) wherein Z_{de} in formula (I_{de}) and/or Zₑₐ in formula (Iₑₐ) and/or Z_{da} in formula (I_{da}) are branched C₂-C₁₀ divalent alkylene groups, preferably branched C₃-C₆ divalent alkylene groups, include, notably, RHODIASOLV® IRIS solvents and RHODIASOLV® POLARCLEAN solvents.

RHODIASOLV® IRIS solvent is a mixture consisting essentially of at least 80% by weight of H₃CO(O)C—CH(CH₃)—CH₂—CH₂—C(O)OCH₃ and H₃CO(O)C—CH(C₂H₅)—CH₂—C(O)OCH₃.

RHODIASOLV® POLARCLEAN solvent is a mixture consisting essentially of at least 80% by weight of H₃CO(O)C—CH(CH₃)—CH₂—CH₂—C(O)N(CH₃)₂ and H₃CO(O)C—CH(C₂H₅)—CH₂—C(O)N(CH₃)₂

According to a second embodiment of the invention, Z_{de} in formula (I_{de}), Zₑₐ in formula (Iₑₐ) and Z_{da} in formula (I_{da}) are linear 02-010 divalent alkylene groups, preferably linear C₃-C₆ divalent alkylene groups.

According to a variant of this second embodiment of the invention, the medium (L) comprises:

(a″) at least one diester of formula (II⁴_{de}), at least one diester of formula (II³_{de}) and at least one diester of formula (II²_{de}), or

(b″) at least one esteramide of formula (II⁴ₑₐ), at least one esteramide of formula (II³ₑₐ) and at least one esteramide of formula (II²ₑₐ), or

(c″) at least one esteramide of formula (II⁴ₑₐ), at least one esteramide of formula (II³ₑₐ), at least one esteramide of formula (II²ₑₐ), at least one diamide of formula (II⁴_{da}), at least one diamide of formula (II³_{da}) and at least one diamide of formula (II²_{da}), or

(d″) mixtures of (a″) and/or (b″) and/or (c″), wherein:

is R¹—OOC—(CH₂)₄—COO—R² (II⁴_{de})

is R¹—OOC—(CH₂)₃—COO—R² (II³_{de})

is R¹—OOC—(CH₂)₂—COO—R² (II²_{de})

is R³—OOC—(CH₂)₄—C(O)NR⁴R⁵ (II⁴ₑₐ)

is R³—OOC—(CH₂)₃—C(O)NR⁴R⁵ (II³ₑₐ)

is R³—OOC—(CH₂)₂—C(O)NR⁴R⁵ (II²ₑₐ)

is R⁵R⁴N(O)C—(CH₂)₄—C(O)NR⁴R⁵ (II⁴_{da})

is R⁵R⁴N(O)C—(CH₂)₃—C(O)NR⁴R⁵ (II³_{da})

is R⁵R⁴N(O)C—(CH₂)₂—C(O)NR⁴R⁵ (II²_{da})

wherein:
R¹ and R², equal to or different from each other, are independently selected from the group consisting of C₁-C₃ alkyl groups,
R³ is selected from the group consisting of C₁-C₂₀ alkyl, C₁-C₂₀ aryl, C₁-C₂₀ alkyaryl and C₁-C₂₀ arylalkyl groups, and
R⁴ and R⁵, equal to or different from each other, are independently selected from the group consisting of C₁-C₂₀ alkyl, C₁-C₂₀ aryl, C₁-C₂₀ alkyaryl, arylalkyl groups, all said groups optionally comprising one or more substituents, optionally having one or more heteroatoms, and cyclic moieties comprising both R⁴ and R⁵ and the nitrogen atom to which they are bound, said cyclic moieties optionally comprising one or more heteroatoms such as oxygen atoms or additional nitrogen atoms.

In above mentioned formulae (II⁴_{de}), (II³_{de}), (II²_{de}), (II⁴ₑₐ), (II³ₑₐ), (II²ₑₐ), (II⁴_{da}), (II³_{da}), (II²_{da}), R¹, R² and R³, equal to or different from each other, are preferably methyl groups, and R⁴ and R⁵, equal to or different from each other, are preferably selected from the group consisting of methyl, ethyl and hydroxyethyl groups.

According to certain preferred variants of this second embodiment of the invention, the medium (L) may comprise:

(aa″) a diester mixture consisting essentially of H₃CO(O)C—(CH₂)₄—C(O)OCH₃, H₃CO(O)C—(CH₂)₃—C(O)OCH₃ and H₃CO(O)C—(CH₂)₂—C(O)OCH₃, or

(bb″) an esteramide mixture consisting essentially of H₃CO(O)C—(CH₂)₄—C(O)N(CH₃)₂, H₃CO(O)C—(CH₂)₃—C(O)N(CH₃)₂ and H₃CO(O)C—(CH₂)₂—C(O)N(CH₃)₂, or

(cc″) a diester mixture of consisting essentially of H₅C₂O(O)C—(CH₂)₄—C(O)OC₂H₅, H₅C₂O(O)C—(CH₂)₃—C(O)OC₂H₅ and H₅C₂O(O)C—(CH₂)₂—C(O)OC₂H₅, or

(dd″) an esteramide mixture consisting essentially of H₅C₂O(O)C—(CH₂)₄—C(O)N(CH₃)₂, H₅C₂O(O)C—(CH₂)₃—C(O)N(CH₃)₂ and H₅C₂O(O)C—(CH₂)₂—C(O)N(CH₃)₂, or

(ee″) an esteramide mixture consisting essentially of H₉C₄O(O)C—(CH₂)₄—C(O)N(CH₃)₂, H₉C₄O(O)C—(CH₂)₃—C(O)N(CH₃)₂ and H₉C₄O(O)C—(CH₂)₂—C(O)N(CH₃)₂, or

(ff″) mixtures thereof.

An exemplary embodiment of the variant listed above under section (aa″) is a diester mixture consisting essentially of:
from 8% to 22% by weight of H₃CO(O)C—(CH₂)₄—C(O)OCH₃,
from 57% to 67% by weight of H₃CO(O)C—(CH₂)₃—C(O)OCH₃ and
from 18% to 28% by weight of H₃CO(O)C—(CH₂)₂—C(O)OCH₃.

Non-limitative examples of suitable diester-based mixtures wherein Z_{de} in formula (I_{de}) and/or Zₑₐ in formula (Iₑₐ) and/or Z_{da} in formula (I_{da}) are linear C₂-C₁₀ divalent alkylene groups, preferably linear C₃-C₆ divalent alkylene groups, include, notably, RHODIASOLV® RPDE solvents.

RHODIASOLV® RPDE solvent is a mixture consisting essentially of at least 70% by weight of H₃CO(O)C—(CH₂)₃—C(O)OCH₃ and H₃CO(O)C—(CH₂)₂—C(O)OCH₃.

The medium (L) may further comprise at least one alkyl acetate of formula (Iₐₐ):

R⁹—OC(O)CH₃ (Iₐₐ)

wherein R⁹ is a linear, branched or cyclic C₃-C₁₅ alkyl group, preferably a C₆-C₁₅ alkyl group, more preferably a C₆-C₁₃ alkyl group, even more preferably a C₆-C₁₂ alkyl group.

In formula (Iₐₐ), R⁹ is preferably selected from the group consisting of cyclohexyl, n-hexyl, n-octyl, isooctyl, n-decyl, isodecyl, undecyl and dodecyl groups.

The alkyl acetate of formula (Iₐₐ) as defined above is preferably a cyclohexyl acetate.

Should the medium (L) further comprise at least one alkyl acetate of formula (Iₐₐ) as defined above, the amount of the alkyl acetate(s) of formula (Iₐₐ) in said medium (L) is typically at most 50% by weight, preferably at most 40% by weight, more preferably at most 30% by weight, with respect to the total weight of the medium (L).

According to a third embodiment of the invention, the medium (L) comprises:

(a′″) at least one diester of formula (I_{de}) and

(b′″) at least one alkyl acetate of formula (Iₐₐ):

R⁹—OC(O)CH₃ (Iₐₐ)

wherein R⁹ is a linear, branched or cyclic C₃-C₁₅ alkyl group, preferably a C₆-C₁₅ alkyl group, more preferably a C₆-C₁₃ alkyl group, even more preferably a C₆-C₁₂ alkyl group.

According to a variant of this third embodiment of the invention, the medium (L) comprises:

(aa′″) a diester mixture consisting essentially of:
from 70% to 95% by weight of at least one diester of formula (I′_{de}),
from 5% to 30% by weight of at least one diester of formula (I″_{de}) and
from 0 to 10% by weight of at least one diester of formula (I′″_{de}), as defined above, and

(bb′″) at least one alkyl acetate of formula (Iₐₐ):

R⁹—OC(O)CH₃ (Iₐₐ)

wherein R⁹ is a linear, branched or cyclic C₃-C₁₅ alkyl group, preferably a C₆-C₁₅ alkyl group, more preferably a C₆-C₁₃ alkyl group, even more preferably a C₆-C₁₂ alkyl group.

According to a preferred variant of this third embodiment of the invention, the medium (L) comprises:

(aa′″) from 50% to 80% by weight, preferably from 60% to 80% by weight of a diester mixture consisting essentially of:
from 70% to 95% by weight of at least one diester of formula (I′_{de}),
from 5% to 30% by weight of at least one diester of formula (I″_{de}) and
from 0 to 10% by weight of at least one diester of formula (I′″_{de}), as defined above, and

(bb′″) from 20% to 50% by weight, preferably from 20% to 40% by weight of at least one alkyl acetate of formula (Iₐₐ):

R⁹—OC(O)CH₃ (Iₐₐ)

wherein R⁹ is a linear, branched or cyclic C₃-C₁₅ alkyl group, preferably a C₆-C₁₅ alkyl group, more preferably a C₆-C₁₃ alkyl group, even more preferably a C₆-C₁₂ alkyl group.

Diesters of formula (I_{de}) which can be used in the composition of the invention can be prepared notably according to the teachings of EP 1991519 A (RHODIA OPERATIONS) Nov. 19, 2008. Esteramides of formula (Iₑₐ), which can be used in the composition of the invention optionally in combination with diamides of formula (I_{da}), can be prepared notably according to the teachings of WO 2011/154661 (RHODIA OPERATIONS) Dec. 15, 2011 and WO 2009/092795 (RHODIA OPERATIONS) Jul. 30, 2009.

The medium (L) may further comprise dimethylsulfoxide (DMSO) and, optionally, at least one further organic solvent different from DMSO and from diesters of formula (I_{de}), esteramides of formula (Iₑₐ) and diamides of formula (I_{da}) as defined above.

The medium (L) is preferably free from DMSO.

Should the medium (L) comprise at least one further organic solvent different from DMSO and from diesters of formula (I_{de}), esteramides of formula (Iₑₐ) and diamides of formula (I_{da}) as defined above, the amount of said organic solvent(s) in said medium (L) is typically lower than 50% by weight, preferably lower than 25% by weight, with respect to the total weight of the medium (L).

Non limitative examples of suitable further organic solvents include, notably, the followings:
aliphatic hydrocarbons including, more particularly, the paraffins such as, in particular, pentane, hexane, heptane, octane, nonane, decane, undecane, dodecane or cyclohexane, and naphthalene and aromatic hydrocarbons and more particularly aromatic hydrocarbons such as, in particular, benzene, toluene, xylenes, cumene, petroleum fractions composed of a mixture of alkylbenzenes,
aliphatic or aromatic halogenated hydrocarbons including more particularly, perchlorinated hydrocarbons such as, in particular, tetrachloroethylene, hexachloroethane; partially chlorinated hydrocarbons such as dichloromethane, chloroform, 1,2-dichloroethane, 1,1,1-trichloroethane, 1,1,2,2-tetrachloroethane, pentachloroethane, trichloroethylene, 1-chlorobutane, 1,2-dichlorobutane, monochlorobenzene, 1,2-dichlorobenzene, 1,3-dichlorobenzene, 1,4-dichlorobenzene, 1,2,4-trichlorobenzene or mixture of different chlorobenzenes,
aliphatic, cycloaliphatic or aromatic ether oxides, more particularly, diethyl oxide, dipropyl oxide, diisopropyl oxide, dibutyl oxide, methyltertiobutylether, dipentyl oxide, diisopentyl oxide, ethylene glycol dimethyl ether, ethylene glycol diethyl ether, ethylene glycol dibutyl ether benzyl oxide; dioxane, tetrahydrofuran (THF),
glycol ethers such as ethylene glycol monomethyl ether, ethylene glycol monoethyl ether, ethylene glycol monopropyl ether, ethylene glycol monoisopropyl ether, ethylene glycol monobutyl ether, ethylene glycol monophenyl ether, ethylene glycol monobenzyl ether, diethylene glycol monomethyl ether, diethylene glycol monoethyl ether, diethylene glycol mono-n-butyl ether,
glycol ether esters such as ethylene glycol methyl ether acetate, ethylene glycol monoethyl ether acetate, ethylene glycol monobutyl ether acetate,
alcohols such as methyl alcohol, ethyl alcohol, diacetone alcohol,
ketones such as acetone, methylethylketone, methylisobutyl ketone, diisobutylketone, cyclohexanone, isophorone,
linear or cyclic esters such as methyl acetoacetate, dimethyl phthalate, γ-butyrolactone,
linear or cyclic carboxamides such as N,N-dimethylacetamide (DMAC), N,N-diethylacetamide, dimethylformamide (DMF), diethylformamide or N-methyl-2-pyrrolidone (NMP),
organic carbonates for example dimethyl carbonate, diethyl carbonate, dipropyl carbonate, dibutyl carbonate, ethylmethyl carbonate, ethylene carbonate, vinylene carbonate,
phosphoric esters such as trimethyl phosphate, triethyl phosphate,
ureas such as tetramethylurea, tetraethylurea.

For embodiments wherein the medium (L) comprises one or more further organic solvents, the medium (L) is preferably free from organic solvents qualified as Carcinogenic, Mutagenic or Toxic to Reproduction according to chemical safety classification (CMR solvents); more specifically, the medium (L) is advantageously substantially free from NMP, DMF and DMAC.

The medium (L) is preferably free from any further organic solvent.

Should the disclosure of any patents, patent applications, and publications which are incorporated herein by reference conflict with the description of the present application to the extent that it may render a term unclear, the present description shall take precedence.

The invention will be now described in more detail with reference to the following examples whose purpose is merely illustrative and not limitative of the scope of the invention.

Raw Materials

Polymer (F-1): VDF (56% by moles)-TrFE (44% by moles)

Polymer (F-2): VDF (75% by moles)-TrFE (25% by moles)

Polymer (F-3): VDF (80% by moles)-TrFE (20% by moles)

Polymer (F-4): VDF (94% by moles)-TrFE (6% by moles)

Polymer (F-5): VDF (89% by moles)-TrFE (11% by moles)

Polymer (F-6): VDF (83% by moles)-TrFE (17% by moles)

Polymer (F-7): VDF (63% by moles)-TrFE (28% by moles)-CTFE (9% by moles)

Solvent (A): RHODIASOLV® IRIS solvent

Solvent (B): composition comprising 70% by weight of RHODIALSOLV®

IRIS solvent and 30% by weight of cyclohexyl acetate.

Solvent (C): RHODIASOLV® RPDE solvent

Solvent (D): RHODIASOLV® POLARCLEAN solvent

Solvent (E): RHODIASOLV® DIB solvent consisting essentially of (H₃C)₂HC—H₂C—O(O)C—(CH₂)₄—C(O)O—CH₂—CH(CH₃)₂, (H₃C)₂HC—H₂C—O(O)C—(CH₂)₃—C(O)O—CH₂—CH(CH₃)₂ and (H₃C)₂HC—H₂C—O(O)C—(CH₂)₂—C(O)O—CH₂—CH(CH₃)₂.

Solvent (F): 2,2-dimethyl-1,3-dioxolane-4-methanol

Manufacture of Polymer (F-1)

In an AISI 316 steel vertical autoclave equipped with a stirrer working at 880 rpm, 1406 g of demineralized water was introduced. The temperature was brought to 14° C. 436 g of vinylidene fluoride and 436 g of trifluoroethylene were fed followed by 713 g of a Ca(OH)₂ solution having a concentration of 40.25 DN/Kg, 26.5 g of a solution of BERMOCOLL® E 230 G ethylhydroxyethyl cellulose with a concentration of 20 g/Kg, 3.11 g of X16 and 8.3 g of diethylenecarbonate. The temperature was then brought to 40° C. until a pressure of 80 bar was reached. The reaction was carried out until the pressure went down to 44 bar. The temperature was then brought to 55° C. Once reached 29 bar, the temperature was brought to 60° C.

When the pressure had reached 8 bar, the reactor was cooled to room temperature and unloaded. The recovered polymer was washed with demineralized water and dried at 100° C. for 16 hours.

Characterization of the polymer (F-1):

Melt Flow Index: 1.68 g/10 minutes

Second melting temperature (Tₘ₂): 156.7° C.

Curie temperature: 64.5° C.

Crystallization temperature: 136° C.

Manufacture of Polymer (F-2)

In an AISI 316 steel vertical autoclave equipped with baffles and stirrer, working at 570 rpm, 3.5 litres of demineralized water was introduced. The temperature was then brought to reaction temperature of 120° C. When this temperature was reached, 32.5 g of a microemulsion prepared according to Example 1 of U.S. Pat. No. 7,122,608 (SOLVAY SOLEXIS S.P.A.) Oct. 17, 2006 and 7.35 bar of vinylidene fluoride were introduced. A gaseous mixture of VDF and TrFE in a molar nominal ratio of 75/25 was fed until reaching a pressure of 30 bar.

The composition of the gaseous mixture in the autoclave head was analyzed by G.C. The gaseous phase was found to be formed of the following compounds in the following molar percentages: 82.5% VDF, 17.5% TrFE. 36 ml of di-tertbutyl peroxide (DTBP) was then fed by means of a metering pump.

The polymerization pressure was maintained constant by feeding the above mentioned monomeric mixture; when 2% of the mixture had been fed, the temperature was lowered to 105° C. When 1150 g of the mixture had been fed, the reaction temperature was kept constant and the pressure was let fall down up to 15 bar. The reactor was then cooled to room temperature, the latex was unloaded and coagulated by freezing for 48 hours. The polymer was finally washed with demineralized water and dried at 100° C.

Characterization of the polymer (F-2):

Melt Flow Index: 5.9 g/10 minutes

Second melting temperature (Tₘ₂): 144.3° C.

Curie temperature: 110° C.

Crystallization temperature: 118.3° C.

Manufacture of Polymer (F-3)

In an AISI 316 steel vertical autoclave equipped with a stirrer working at 880 rpm, 1406 g of demineralized water was introduced. The temperature was brought to 14° C. 841 g of vinilidene difluoride, 207 g of trifluoroethylene were fed followed by 713 g of Ca(OH)₂ solution having a concentration of 40.25 DN/Kg, 26.5 g of a solution of BERMOCOLL® E 230 G ethylhydroxyethyl cellulose with a concentration of 20 g/Kg, 3.11 g of X16 and 8.3 g of diethylenecarbonate. The temperature was brought to 40° C. until a pressure of 80 bar was reached. The reaction was carried out until the pressure went down to 46 bar. The temperature was then brought to 50° C. Once reached 37.5 bars, the temperature was brought to 60° C. When the pressure had reached 7 bar, the reactor was cooled to room temperature and unloaded. The recovered polymer was washed with demineralized water and dried at 100° C. for 16 hours.

Characterization of the polymer (F-3):

Melt Flow Index: 2.9 g/10 minutes

Second melting temperature (Tₘ₂): 149.7° C.

Curie temperature: 117.77° C.

Crystallization temperature: 128° C.

Manufacture of polymer (F-4)

In an AISI 316 steel vertical autoclave equipped with baffles and stirrer, working at 570 rpm, 3.5 litres of demineralized water was introduced. The temperature was then brought to reaction temperature of 120° C. When this temperature was reached, 32.5 g of a microemulsion prepared according to Example 1 of U.S. Pat. No. 7,122,608 (SOLVAY SOLEXIS S.P.A.) Oct. 17, 2006 and 11.5 bar of vinylidene fluoride were introduced. A gaseous mixture of VDF and TrFE in a molar nominal ratio of 94/6 was fed until reaching a pressure of 30 bar.

The composition of the gaseous mixture in the autoclave head was analyzed by G.C. The gaseous phase was found to be formed of the following compounds in the following molar percentages: 96.2% VDF, 3.8% TrFE. 42 ml of di-tertbutyl peroxide (DTBP) was then fed by means of a metering pump.

The polymerization pressure was maintained constant by feeding the above mentioned monomeric mixture; when 2% of the mixture had been fed, the temperature was lowered to 105° C. When 675 g of the mixture had been fed, the reaction temperature was kept constant and the pressure was let fall down up to 15 bar. The reactor was then cooled to room temperature, the latex was unloaded and coagulated by freezing for 48 hours. The polymer was finally washed with demineralized water and dried at 100° C.

Characterization of the polymer (F-4):

Melt Flow Index: 18.1 g/10 minutes

Second melting temperature (Tₘ₂): 140.52° C.

Curie temperature: Not present

Crystallization temperature: 120.37° C.

Manufacture of Polymer (F-5)

The same procedure for the manufacture of the polymer (F-3) was followed but 918 g of vinylidene fluoride and 114 g of trifluoroethylene were fed.

Characterization of the polymer (F-5):

Melt Flow Index: 8.2 g/10 minutes

Second melting temperature (Tₘ₂): 163.7° C.

Curie temperature: 149.9° C.

Crystallization temperature: 125.8° C.

Manufacture of Polymer (F-6)

The same procedure for the manufacture of the polymer (F-2) was followed but 9.2 bar of vinylidene fluoride was introduced and a gaseous mixture of VDF and TrFE in a molar nominal ratio of 83/17 was fed until reaching a pressure of 30 bar.

The gaseous phase was found to be formed of the following compounds in the following molar percentages: 85.7% VDF, 14.3% TrFE.

Characterization of the polymer (F-6):

Melt Flow Index: 105 g/10 minutes

Second melting temperature (Tₘ₂): 138.12° C.

Curie temperature: 129.8° C.

Crystallization temperature: 123.6° C.

Manufacture of Polymer (F-7)

In an AISI 316 steel vertical autoclave equipped with baffles and stirrer, working at 570 rpm, 3.5 litres of demineralized water was introduced. The temperature was then brought to reaction temperature of 120° C. When this temperature was reached, 32.5 g of a microemulsion prepared according to Example 1 of U.S. Pat. No. 7,122,608 (SOLVAY SOLEXIS S.P.A.) Oct. 17, 2006, 5 bar of vinylidene fluoride and 0.5 bar of chlorotrifluoroethylene were introduced. A gaseous mixture of VDF, TrFE and CTFE in a molar nominal ratio of 63/28/9 was fed until reaching a pressure of 30 bar.

The composition of the gaseous mixture in the autoclave head was analyzed by G.C. The gaseous phase was found to be formed of the following compounds in the following molar percentages: 81.6% VDF, 11.9% TrFE and 6.5% CTFE. 20 ml of di-tertbutyl peroxide (DTBP) was then fed by means of a metering pump.

The polymerization pressure was maintained constant by feeding the above mentioned monomeric mixture; when 2% of the mixture had been fed, the temperature was lowered to 105° C. When 587 g of the mixture had been fed, the reaction temperature was kept constant and the pressure was let fall down up to 15 bar. The reactor was then cooled to room temperature, the latex was unloaded and coagulated by freezing for 48 hours. The polymer was finally washed with demineralized water and dried at 80° C. for 48 hours.

Characterization of the polymer (F-7):

Melt Flow Index: 14.4 g/10 minutes

Second melting temperature: 118.6° C.

Curie temperature: 20.9° C.

Determination of Fluoropolymer Chain Ends

Fluoropolymer chain ends were determined according to the method described in PIANCA, M., et al. End groups in fluoropolymers. Journal of Fluorine Chemistry. 1999, vol. 95, p.71-84. Concentration of relevant chain ends are expressed as mmoles per kg of VDF recurring units.

Composition and properties of the fluoropolymers so obtained are summarized in Table 1.

TABLE 1

| | TrFE | VDF | CTFE | Total chain ends |
|---|---|---|---|---|
| | [% mol] | [% mol] | [% mol] | [mmol/kg of VDF] |
| Polymer (F-1) | 44% | 56% | — | 16 |
| Polymer (F-2) | 25% | 75% | — | 92 |
| Polymer (F-3) | 20% | 80% | — | 15 |
| Polymer (F-4) | 6% | 94% | — | 76 |
| Polymer (F-5) | 11% | 89% | — | 13 |
| Polymer (F-6) | 17% | 83% | — | 144 |
| Polymer (F-7) | 28% | 63% | 9% | 69 |

Determination of Solubility of the Fluoropolymer Compositions

The solubility of a fluoropolymer in a solvent was measured by using a Leica CLS 150 Led fiber optic light source microscope Illuminator.

Data regarding dissolution properties of the fluoropolymer compositions so obtained are summarized in Tables 2 to 4 hereinbelow.

A solution of a fluoropolymer in a solvent was obtained when the resulting mixture was clear and no phase separation was visible in the system as indicated by symbol “S” (soluble) in Table 2 hereinbelow.

A dispersion of a fluoropolymer in a liquid medium was obtained when the resulting mixture was turbid or cloudy due to formation of polymer aggregates as indicated by symbol “I” (insoluble) in Tables 3 and 4 hereinbelow.

### EXAMPLE 1

A fluoropolymer composition was manufactured by dissolving, under stirring, either at 25° C. or at 50° C., any of polymer (F-1), polymer (F-2), polymer (F-3) or polymer (F-7) in the form of particles in solvent (A). The fluoropolymer composition was kept stirred until complete dissolution of the polymer (F) in the medium (L).

### EXAMPLE 2

A fluoropolymer composition was manufactured by dissolving, under stirring, either at 25° C. or at 50° C., any of polymer (F-1), polymer (F-2), polymer (F-3) or polymer (F-7) in the form of particles in solvent (B). The fluoropolymer composition was kept stirred until complete dissolution of the polymer (F) in the medium (L).

### EXAMPLE 3

A fluoropolymer composition was manufactured by dissolving, under stirring, either at 25° C. or at 50° C., any of polymer (F-1), polymer (F-2), polymer (F-3) or polymer (F-7) in the form of particles in solvent (C). The fluoropolymer composition was kept stirred until complete dissolution of the polymer (F) in the medium (L).

### EXAMPLE 4

A fluoropolymer composition was manufactured by dissolving, under stirring, either at 25° C. or at 50° C., any of polymer (F-1), polymer (F-2), polymer (F-3) or polymer (F-7) in the form of particles in solvent (D). The fluoropolymer composition was kept stirred until complete dissolution of the polymer (F) in the medium (L).

### COMPARATIVE EXAMPLE 1

A fluoropolymer composition was manufactured by dispersing, under stirring, either at 25° C. or at 50° C., any of polymer (F-4), polymer (F-5) or polymer (F-6) in the form of particles in solvent (A).

### COMPARATIVE EXAMPLE 2

A fluoropolymer composition was manufactured by dispersing, under stirring, either at 25° C. or at 50° C., any of polymer (F-4), polymer (F-5) or polymer (F-6) in the form of particles in solvent (B).

### COMPARATIVE EXAMPLE 3

A fluoropolymer composition was manufactured by dispersing, under stirring, either at 25° C. or at 50° C., any of polymer (F-4), polymer (F-5) or polymer (F-6) in the form of particles in solvent (C).

### COMPARATIVE EXAMPLE 4

A fluoropolymer composition was manufactured by dispersing, under stirring, either at 25° C. or at 50° C., any of polymer (F-4), polymer (F-5) or polymer (F-6) in the form of particles in solvent (D).

### COMPARATIVE EXAMPLE 5

A fluoropolymer composition was manufactured by dispersing, under stirring, either at 25° C. or at 50° C., any of polymer (F-1), polymer (F-2), polymer (F-3), polymer (F-4), polymer (F-5), polymer (F-6) or polymer (F-7) in the form of particles in a liquid medium consisting of the solvent (E).

### COMPARATIVE EXAMPLE 6

A fluoropolymer composition was manufactured by dispersing, under stirring, either at 25° C. or at 50° C., any of polymer (F-1), polymer (F-2), polymer (F-3), polymer (F-4), polymer (F-5), polymer (F-6) or polymer (F-7) in the form of particles in a liquid medium consisting of the solvent (F).

As shown in Table 2 hereinbelow, any of polymer (F-1), polymer (F-2), polymer (F-3) or polymer (F-7) advantageously dissolved in any of solvent (A), solvent (B), solvent (C) or solvent (D) thereby providing clear solutions with no phase separation up to 30% by weight, with respect to the total weight of said solution, of said polymer (F-1), polymer (F-2), polymer (F-3) or polymer (F-7).

In particular, polymer (F-2) and polymer (F-7) provided for faster dissolution in any of solvent (A), solvent (B), solvent (C) or solvent (D) thereby providing homogeneous solutions comprising up to 30% by weight, with respect to the total weight of said solution, of said polymer (F-2) or polymer (F-7).

TABLE 2

| | Ex. 1 | | Ex. 2 | | Ex. 3 | | Ex. 4 | |
|---|---|---|---|---|---|---|---|---|
| | Solvent (A) | | Solvent (B) | | Solvent (C) | | Solvent (D) | |
| | 25° C. | 50° C. | 25° C. | 50° C. | 25° C. | 50° C. | 25° C. | 50° C. |
| Polymer (F-1) | 25% S | 25% S | 25% S | 25% S | 25% S | 25% S | 25% S | 25% S |
| Polymer (F-2) | 25% S | 25% S | 25% S | 25% S | 25% S | 25% S | 25% S | 25% S |
| Polymer (F-3) | 25% S | 25% S | 10% S | 10% S | 20% S | 20% S | 20% S | 20% S |
| Polymer (F-7) | 30% S | 30% S | 15% S | 15% S | 20% S | 20% S | 20% S | 20% S |

On the other hand, as shown in Table 3 hereinbelow, the fluoropolymer compositions according to Comparative Examples 1 to 4 were turbid or cloudy due to formation of polymer aggregates even at 5% by weight, with respect to the total weight of said composition, of polymer (F-4), polymer (F-5) or polymer (F-6) in any of solvent (A), solvent (B), solvent (C) or solvent (D).

TABLE 3

| | C. Ex. 1 | | C. Ex. 2 | | C. Ex. 3 | | C. Ex. 4 | |
|---|---|---|---|---|---|---|---|---|
| | Solvent (A) | | Solvent (B) | | Solvent (C) | | Solvent (D) | |
| | 25° C. | 50° C. | 25° C. | 50° C. | 25° C. | 50° C. | 25° C. | 50° C. |
| Polymer (F-4) | 5% I | 5% I | 10% I | 10% I | 5% I | 5% I | 25% I | 25% I |
| Polymer (F-5) | 10% I | 10% I | 10% I | 10% I | 10% I | 10% I | 10% I | 10% I |
| Polymer (F-6) | 10% I | 10% I | 10% I | 10% I | 10% I | 10% I | 25% I | 25% I |

Also, as shown in Table 4 hereinbelow, the fluoropolymer compositions according to Comparative Examples 5 and 6 were turbid or cloudy due to formation of polymer aggregates even at 1% by weight, with respect to the total weight of said composition, of polymer (F-1), polymer (F-2), polymer (F-3), polymer (F-4), polymer (F-5), polymer (F-6) or polymer (F-7) in any of solvent (E) or solvent (F).

TABLE 4

| | |
|---|---|
| C. Ex. 5 | C. Ex. 6 |
| Solvent (E) | Solvent (F) |

| | 25° C. | 50° C. | 25° C. | 50° C. |
|---|---|---|---|---|
| Polymer (F-1) | 1% I | 1% I | 1% I | 1% I |
| Polymer (F-2) | 1% I | 1% I | 1% I | 1% I |
| Polymer (F-3) | 1% I | 1% I | 1% I | 1% I |
| Polymer (F-4) | 1% I | 1% I | 1% I | 1% I |
| Polymer (F-5) | 1% I | 1% I | 1% I | 1% I |
| Polymer (F-6) | 1% I | 1% I | 1% I | 1% I |
| Polymer (F-7) | 1% I | 1% I | 1% I | 1% I |

The composition (C) according to the present invention may be advantageously used in a process for the manufacture of fluoropolymer films thereby providing for homogeneous fluoropolymer films having good mechanical properties to be suitably used in various applications including electrical or electronic devices.

1. A composition [composition (C)] comprising:
(A) at least one fluoropolymer [polymer (F)] comprising:
from 30% to 82% by moles, with respect to the total amount by moles of recurring units of the polymer (F), of recurring units derived from vinylidene fluoride (VDF) and
from 18% to 70% by moles, with respect to the total amount by moles of recurring units of the polymer (F), of recurring units derived from trifluoroethylene (TrFE) and, optionally, at least one fluorinated monomer [monomer (F)] different from VDF and TrFE, and
(B) a liquid medium [medium (L)] comprising one or more organic solvents selected from the group consisting of diesters of formula (I_{de}), esteramides of formula (Iₑₐ) and diamides of formula (I_{da}):
R¹O(O)C—Z_{de}—C(O)OR² (I_{de})
R³O(O)C—Zₑₐ—C(O)NR⁴R⁵ (Iₑₐ)
R⁵R⁴N(O)C—Z_{da}—C(O)NR⁴R⁵ (I_{da})
wherein:
R¹ and R², equal to or different from each other, are independently selected from the group consisting of C₁-C₃ hydrocarbon groups,
R³ is selected from the group consisting of C₁-C₂₀ hydrocarbon groups, and
R⁴ and R⁵, equal to or different from each other, are independently selected from the group consisting of hydrogen and C₁-C₃₆ hydrocarbon groups, optionally substituted, or wherein R⁴ and R⁵, taken together, form a cyclic moiety including the nitrogen atom to which they are bound, said cyclic moiety being optionally substituted and/or optionally comprising one or more heteroatoms, and mixtures thereof, and
Z_{de}, Zₑₐ and Z_{da}, equal to or different from each other, are independently linear or branched C₂-C₁₀ divalent alkylene groups.

2. The composition (C) according to claim 1, wherein the medium (L) is free from dimethylsulfoxide (DMSO).

3. The composition (C) according to claim 1, wherein the polymer (F) comprises:
from 45% to 81% by moles, with respect to the total amount by moles of recurring units of the polymer (F), of recurring units derived from vinylidene fluoride (VDF),
from 19% to 55% by moles, with respect to the total amount by moles of recurring units of the polymer (F), of recurring units derived from trifluoroethylene (TrFE) and
optionally, from 0.01% to 15% by moles, with respect to the total amount by moles of recurring units of the polymer (F), of recurring units derived from at least one hydrogenated monomer (H).

4. The composition (C) according to claim 1, wherein the polymer (F) comprises:
from 30% to 80% by moles, with respect to the total amount by moles of recurring units of the polymer (F), of recurring units derived from vinylidene fluoride (VDF),
from 19% to 55% by moles, with respect to the total amount by moles of recurring units of the polymer (F), of recurring units derived from trifluoroethylene (TrFE),
from 1% to 15% by moles, with respect to the total amount by moles of recurring units of the polymer (F), of recurring units derived from at least one monomer (F) different from VDF and TrFE and
optionally, from 0.01% to 8% by moles, with respect to the total amount by moles of recurring units of the polymer (F), of recurring units derived from at least one hydrogenated monomer (H).

5. The composition (C) according to claim 1, wherein the polymer (F) comprises one or more chain branches comprising end groups of formulae —CF₂H and/or —CF₂CH₃.

6. The composition (C) according to claim 1, wherein the polymer (F) comprises one or more chain branches comprising end groups of formulae —CF₂H and/or —CF₂CH₃ in an amount of at least 30 mmoles/Kg per Kg of vinylidene fluoride (VDF) recurring units.

7. The composition (C) according to claim 1, wherein the medium (L) comprises a total amount of one or more organic solvents selected from the group consisting of diesters of formula (I_{de}), esteramides of formula (Iₑₐ) and diamides of formula (I_{da}) of at least 50% by weight with respect to the total weight of the medium (L).

8. The composition (C) according to claim 1, said composition (C) comprising:
(A) from 0.1% to 40% by weight of at least one polymer (F) and
(B) from 60% to 99.9% by weight of a medium (L).

9. The composition (C) according to claim 1, said composition (C) further comprising one or more additives selected from the group consisting of crosslinking agents and crosslinking initiators.

10. A process for the manufacture of the composition (C) according to claim 1, said process comprising:
heating a mixture comprising at least one polymer (F) and a medium (L), under stirring,
thereby providing the composition (C).

11. The process according to claim 10, wherein the polymer (F) in the mixture is used either in the form of particles or in the form of pellets.

12. The process according to claim 10, wherein the mixture is heated under stirring at a temperature of at least 20° C.

13. The process according to claim 10, wherein the mixture is heated under stirring at a temperature of at most 80° C.

14. A process for the manufacture of a fluoropolymer film [film (F)], said process comprising:
applying a composition (C) according to claim 1 onto at least one surface of a substrate thereby providing a wet film, and drying the wet film thereby providing the fluoropolymer film [film (F)].

15. A process for the manufacture of an electrical or electronic device, said process comprising:
(i″) manufacturing a fluoropolymer film [film (F)] according to the process of claim 14, and
(ii″) using the film (F) provided in step (i″) for manufacturing said electrical or electronic device.

16. The process according to claim 14, wherein the wet film is dried at a temperature comprised between 60° C. and 200° C.
